(19) United States
(12) Patent Application Publication
(10) Pub. No.: US 2024/0274610 A1
(43) Pub. Date: Aug. 15, 2024

(54) DISPLAY SUBSTRATE, DISPLAY PANEL, AND DISPLAY DEVICE

(71) Applicants: Fuzhou BOE Optoelectronics Technology Co., Ltd., Fuzhou, Fujian (CN); BOE Technology Group Co., Ltd., Beijing (CN)

(72) Inventors: Liqing YAO, Beijing (CN); Xu XU, Beijing (CN); Tao FANG, Beijing (CN); Yixu YANG, Beijing (CN); Wenli FAN, Beijing (CN); Zecun ZENG, Beijing (CN)

(21) Appl. No.: 18/022,259

(22) PCT Filed: Mar. 30, 2022
(86) PCT No.: PCT/CN2022/084202

§ 371 Date: Feb. 20, 2023

(51) Int. Cl. H01L 27/12; G02F 1/1343; G02F 1/1362; G02F 1/1368

(52) U.S. Cl. CPC H01L 27/124; G02F 1/134372; G02F 1/136286; G02F 1/1368

(57) ABSTRACT

Provided in the present disclosure are a display substrate, a display panel, and a display device. The display substrate includes: a base substrate; a plurality of gate lines located on a side of the base substrate, and extending in a first direction; and a plurality of pixel electrodes, distributed in arrays, where pixel electrodes in the same row are electrically connected to at least one gate line, and in the pixel electrodes in the same row, at least adjacent parts of two adjacent pixel electrodes are distributed in a split-level manner.

### CROSS REFERENCE TO RELATED APPLICATIONS

The present disclosure is a US National Stage of International Application No. PCT/CN2022/084202, filed on Mar. 30, 2022, the entire contents of which are incorporated herein by reference.

### FIELD

The present disclosure relates to the field of semiconductor technologies, and in particular to a display substrate, a display panel, and a display device.

### BACKGROUND

In recent years, the field of 3D display has been developing rapidly. Grating 3D display devices have attracted much attention due to the advantages of simple process and low crosstalk. Usually, a grating 3D display device includes a display panel and a grating. The left eye and right eye of a viewer acquire a left eye view and a right eye view displayed by the display panel respectively through the grating to form a 3D display image.

### SUMMARY

The present disclosure provides a display substrate, a display panel, and a display device. The display substrate includes: a base substrate: a plurality of gate lines, where the plurality of gate lines are located on a side of the base substrate, and extend in a first direction; and a plurality of pixel electrodes, where the plurality of pixel electrodes are distributed in arrays, pixel electrodes in the same row are electrically connected to at least one gate line, and in the pixel electrodes in the same row, at least adjacent parts of two adjacent pixel electrodes are distributed in a split-level manner.

In a possible implementation, the display substrate includes two laminated electrode layers, and the two electrode layers include a first electrode layer and a second electrode layer located on a side of the first electrode layer away from the base substrate; and the plurality of pixel electrodes are distributed in the two electrode layers.

In a possible implementation, in the pixel electrodes in the same row, the same pixel electrode is located in the same electrode layer, and two adjacent pixel electrodes are respectively located in different electrode layers.

In a possible implementation, each pixel electrode includes a framework portion with a body direction extending perpendicular to the first direction and branch portions extending from two side edges of the framework portion.

In a possible implementation, each pixel electrode includes two framework portions with a body direction extending perpendicular to the first direction and having a gap, and branch portions extending from a side of each framework portion away from the gap; and the display substrate further includes: a connecting portion extending in the first direction, where an orthographic projection of the connecting portion onto the base substrate is at least located in the gap between the two framework portions, and the two framework portions of the same pixel electrode are connected by the connecting portion.

In a possible implementation, each pixel electrode includes a first sub-electrode and a second sub-electrode sequentially arranged parallel to the first direction, the first sub-electrode and the second sub-electrode of the same pixel electrode are respectively located in different electrode layers, and the first sub-electrode and the second sub-electrode of the same pixel electrode are in communication through a via hole.

In a possible implementation, each of the first sub-electrode and the second sub-electrode includes: a framework portion with a body direction extending perpendicular to the first direction and branch portions extending from a side of each framework portion away from the other framework portion.

In a possible implementation, an orthographic projection of the framework portion of the first sub-electrode onto the base substrate is approximately overlapped with an orthographic projection of the framework portion of the second sub-electrode onto the base substrate.

In a possible implementation, an orthographic projection of the framework portion of the first sub-electrode onto the base substrate and an orthographic projection of the framework portion of the second sub-electrode onto the base substrate are parallel to each other, and have a gap therebetween.

In a possible implementation, the first sub-electrode further includes: a first portion connected to the framework portion and extending away from a side of the second sub-electrode; the second sub-electrode further includes: an extending portion connected to the framework portion and extending toward a side of the first sub-electrode; and an orthographic projection of the first portion onto the base substrate and an orthographic projection of the extending portion onto the base substrate have an overlap region, and the first portion and the extending portion are connected by a perforation at the overlap region.

In a possible implementation, the second sub-electrode further includes a protruding portion, and the protruding portion is configured to be electrically connected a source or a drain; and the extending portion and the protruding portion are located at the same end of the pixel electrode to which the extending portion and the protruding portion belong.

In a possible implementation, the display substrate further includes a data line with a body direction extending perpendicular to the first direction, and further includes a common electrode layer; and a partial orthographic projection of the data line onto the base substrate is located in a region in which the orthographic projection of the pixel electrode onto the base substrate is located.

In a possible implementation, when the pixel electrode includes one framework portion, an orthographic projection of the data line onto the base substrate is approximately overlapped with an orthographic projection of the framework portion onto the base substrate.

In a possible implementation, when the pixel electrode includes two framework portions and orthographic projections of the two framework portions onto the base substrate are approximately overlapped, an orthographic projection of the data line onto the base substrate is approximately overlapped with the orthographic projections of the framework portions onto the base substrate.

In a possible implementation, the data line is located between the first electrode layer and the base substrate; and the display substrate further includes an organic film layer located between the first electrode layer and the data line.

In a possible implementation, when the pixel electrode includes two framework portions and the two framework portions have a gap, an orthographic projection of the data line onto the base substrate is located in the gap between the two framework portions at the base substrate.

In a possible implementation, the data line is located in the first electrode layer: or the data line is located between the first electrode layer and the base substrate.

In a possible implementation, in a direction parallel to the first direction and in the pixel electrodes in the same row: a minimum spacing between two adjacent pixel electrodes ranges from 0 μm to 2 μm.

An embodiment of the present disclosure further provides a display panel, including the display substrate provided in the foregoing embodiment of the present disclosure.

An embodiment of the present disclosure further provides a display device, including the display panel provided in the foregoing embodiment of the present disclosure.

### BRIEF DESCRIPTION OF THE DRAWINGS

FIG. 1 is a schematic structural diagram of a 3D display device.

FIG. 2 is a schematic structural diagram of a pixel electrode in the related art.

FIG. 3A is a schematic structural diagram along a dash line AA1 in FIG. 3B.

FIG. 3B is a schematic top view 1 of a display substrate according to an embodiment of the present disclosure.

FIG. 3C is a schematic diagram of a pixel electrode in FIG. 3B.

FIG. 3D is a schematic diagram of a pixel electrode of a first electrode layer in FIG. 3B.

FIG. 3E is a schematic diagram of a pixel electrode of a second electrode layer in FIG. 3B.

FIG. 4A is a schematic structural diagram along a dash line AA1 in FIG. 4B.

FIG. 4B is a schematic top view 2 of a display substrate according to an embodiment of the present disclosure.

FIG. 4C is a schematic diagram of a pixel electrode in FIG. 4B.

FIG. 4D is a schematic diagram of a pixel electrode of a first electrode layer in FIG. 4B.

FIG. 4E is a schematic diagram of a pixel electrode of a second electrode layer in FIG. 4B.

FIG. 5A is a schematic structural diagram along a dash line AA1 in FIG. 5B.

FIG. 5B is a schematic top view 3 of a display substrate according to an embodiment of the present disclosure.

FIG. 5C is a schematic diagram of a pixel electrode in FIG. 5B.

FIG. 5D is a schematic diagram of a pixel electrode of a first electrode layer in FIG. 5B.

FIG. 5E is a schematic diagram of a pixel electrode of a second electrode layer in FIG. 5B.

FIG. 6A is a schematic structural diagram along a dash line AA1 in FIG. 6B.

FIG. 6B is a schematic top view 4 of a display substrate according to an embodiment of the present disclosure.

FIG. 6C is a schematic diagram of a pixel electrode in FIG. 6B.

FIG. 6D is a schematic diagram of a pixel electrode of a first electrode layer in FIG. 6B.

FIG. 6E is a schematic diagram of a pixel electrode of a second electrode layer in FIG. 6B.

FIG. 7 is a schematic diagram of extension directions of different branch portions according to an embodiment of the present disclosure.

FIG. 8A is a schematic diagram 5 of a display substrate according to an embodiment of the present disclosure.

FIG. 8B is a schematic cross-sectional view along a dash line AA1 in FIG. 8A.

FIG. 9A is a schematic diagram 6 of a display substrate according to an embodiment of the present disclosure.

FIG. 9B is a schematic cross-sectional view 1 along a dash line AA1 in FIG. 9A.

FIG. 9C is a schematic cross-sectional view 2 along a dash line AA1 in FIG. 9A.

FIG. 9D is a schematic cross-sectional view 3 along a dash line AA1 in FIG. 9A.

FIG. 10A is a schematic diagram 7 of a display substrate according to an embodiment of the present disclosure.

FIG. 10B is a schematic cross-sectional view along a dash line AA1 in FIG. 10A.

FIG. 11A is a schematic diagram 8 of a display substrate according to an embodiment of the present disclosure.

FIG. 11B is a schematic cross-sectional view along a dash line AA1 in FIG. 11A.

FIG. 12 is a schematic top view of a data line according to an embodiment of the present disclosure.

### DETAILED DESCRIPTION OF THE EMBODIMENTS

To make the objectives, technical solutions, and advantages of the embodiments of the present disclosure clearer, the following clearly and completely describes the technical solutions in embodiments of the present disclosure with reference to the accompanying drawings in embodiments of the present disclosure. Apparently, the described embodiments are some rather than all of the embodiments of the present disclosure. All other embodiments obtained by persons of ordinary skill in the art based on the described embodiments of the present disclosure without creative efforts shall fall within the protection scope of the present disclosure.

Unless otherwise defined, the technical terms and scientific terms used in the present disclosure have the same meaning as how they are generally understood by those of ordinary skill in the art to which the present disclosure pertains. Terms such as “first” and “second” used in the present disclosure are only used to distinguish different components and do not intend to indicate any order, number or importance. Similar terms such as “comprise” or “include” means that an element or object in front of the term covers elements or objects listed behind the term but do not exclude other elements or objects. Terms such as “connection” or “connected” are not limited to a physical or mechanical connection, and may include an electrical connection, which may be a direct electrical connection or an indirect electrical connection. “Up”, “down”, “left”, “right”, and the like are only used to represent a relative location relationship. The relative location relationship may be correspondingly changed after the absolute locations of described objects are changed.

As used herein, “approximately” or “substantially the same” includes a stated value and implies a range of acceptable deviations from a specific value as determined by those of ordinary skill in the art, taking into consideration the measurement under discussion and the error associated with the measurement of a specific quantity (i.e., the limitations of a measurement system). For example, “approximately the same” may mean that a difference with respect to the stated value is within one or more standard deviations, or within +30%, 20%, 10%, or 5%.

In the accompanying drawings, the thickness of a layer, film, panel, region, etc, is enlarged for clarity. Exemplary implementations are described herein with reference to cross-sectional drawings as schematic diagrams of idealized implementations. In this case, deviations from the shape of a drawing as a result of, for example, manufacturing techniques and/or tolerances will be expected. Therefore, the implementations described herein should not be interpreted as being limited to a specific shape of a region shown herein, but include deviations in shape resulting from, for example, manufacturing. For example, a region illustrated or described as flat may typically have a rough and/or a nonlinear feature. In addition, a sharp corner illustrated may be rounded. Therefore, regions illustrated are schematic in nature and their shapes are not intended to be the exact shapes of the illustrated regions and are not intended to limit the scope of the present claims.

To keep the following description of embodiments of the present disclosure clear and concise, the present disclosure omits detailed descriptions of known functions and known components.

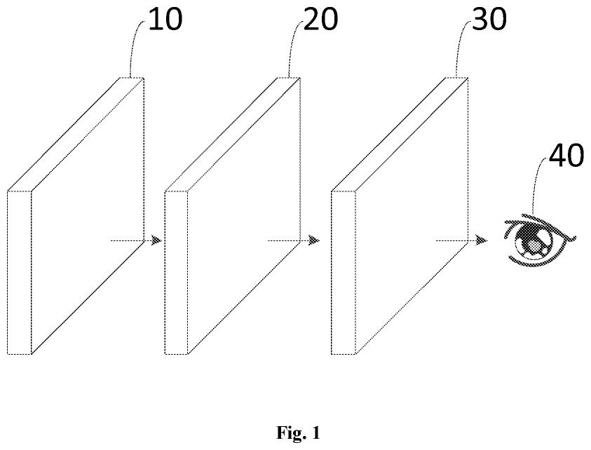

As shown in FIG. 1, a glasses-free 3D display device uses a combined stacking mode of a light source 10, a display panel 20, and a grating 30. The display panel 20 receives an external signal, and displays a two-dimensional image; and then implements parallax through refraction of the grating 30 in front of a screen, to form three-dimensional perception, to enable a viewer 40 to see a 3D image.

During the use of a grating glasses-free 3D display device, due to the impact of a manufacturing process of a display panel or other factors, moiré patterns are generated in a formed 3D display image, to thereby affect a 3D display effect.

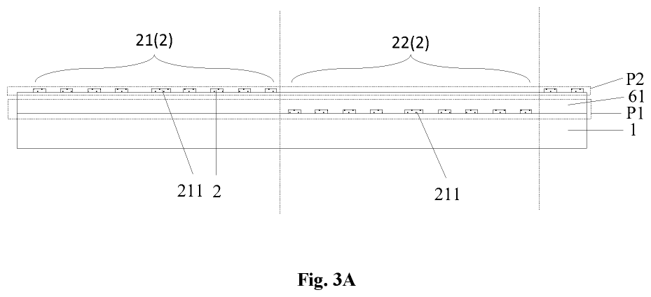

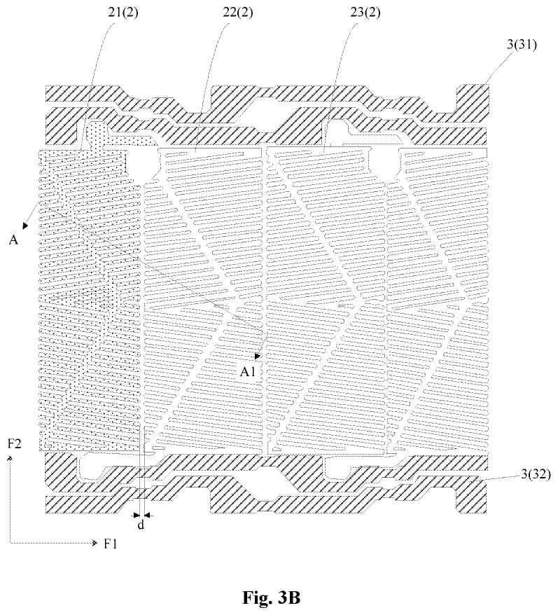

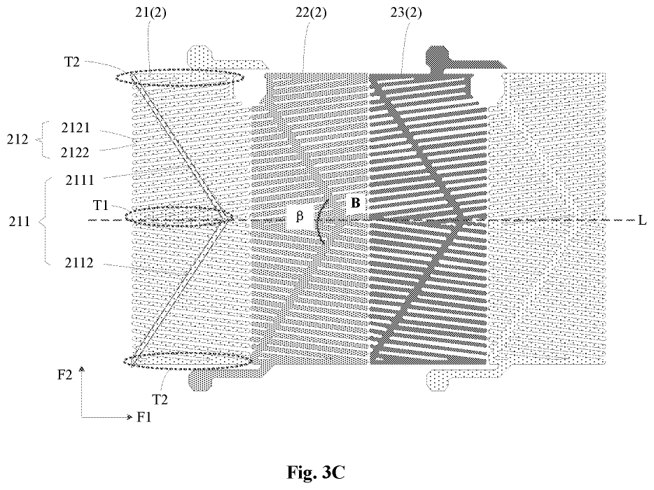

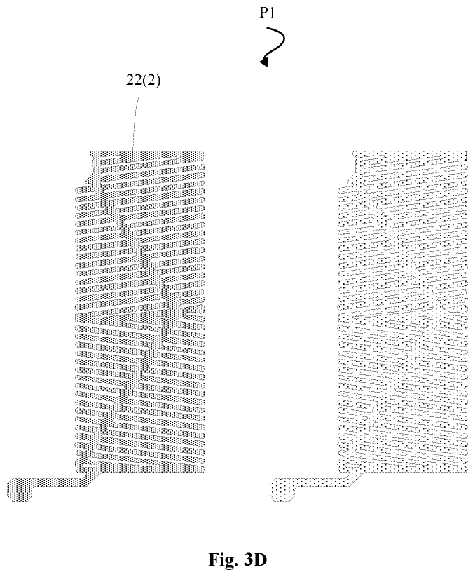

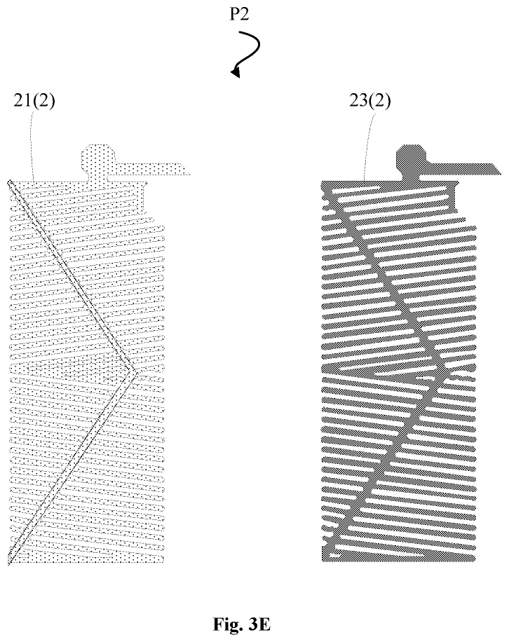

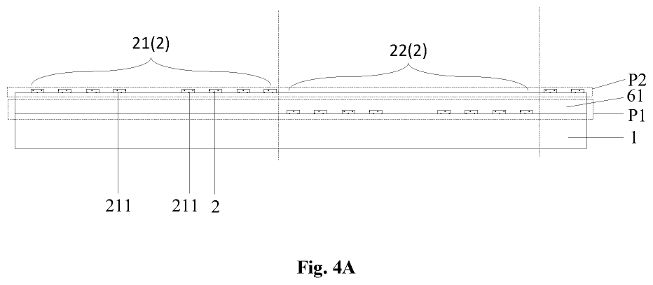

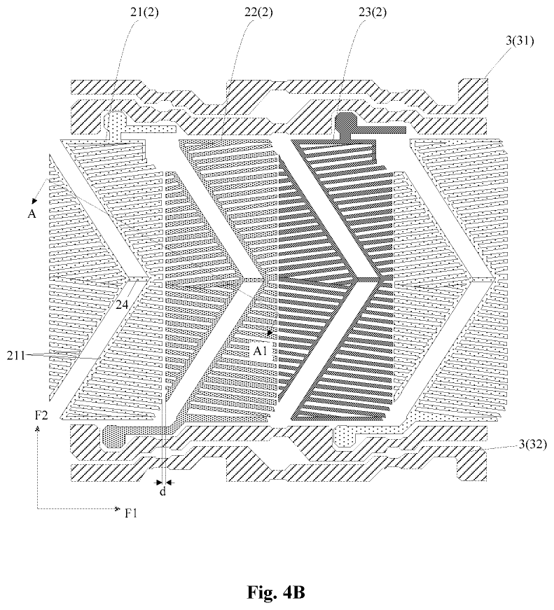

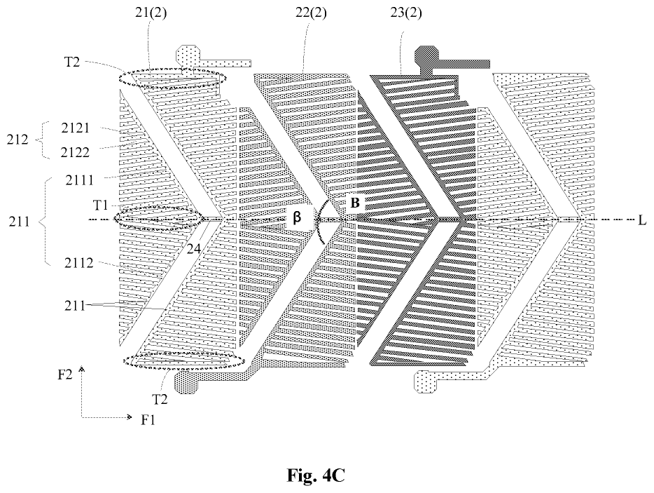

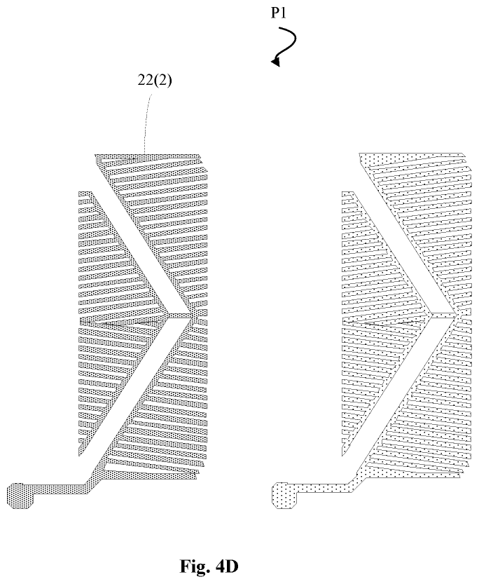

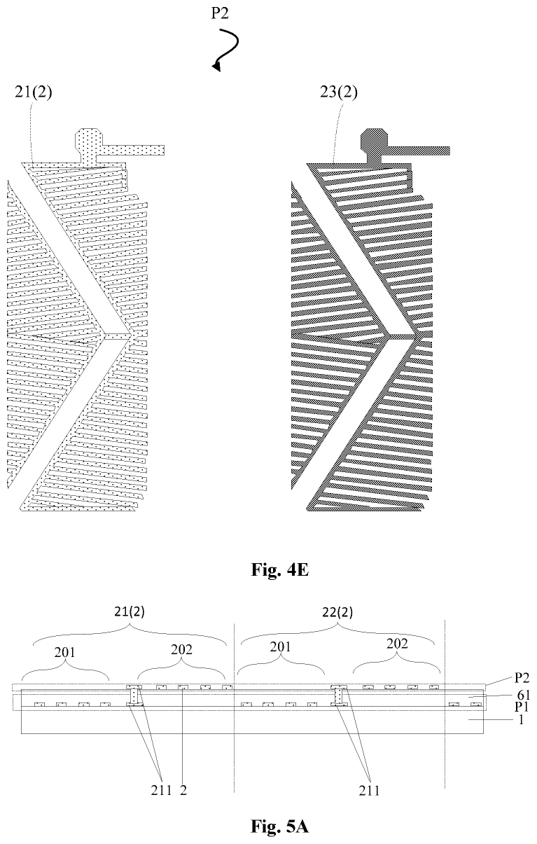

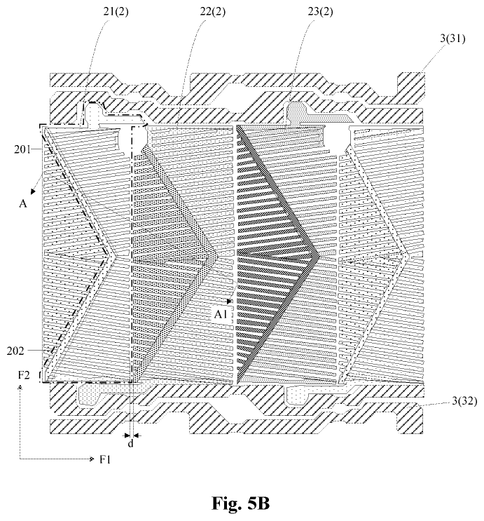

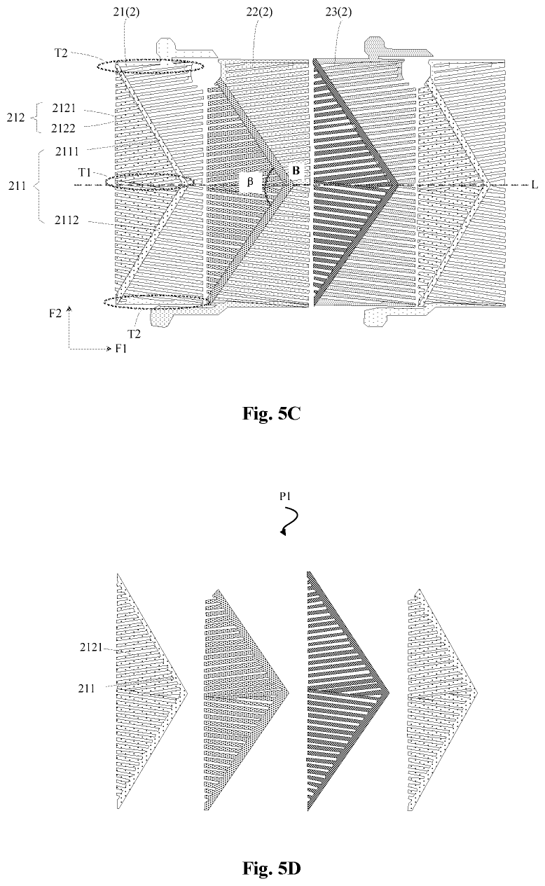

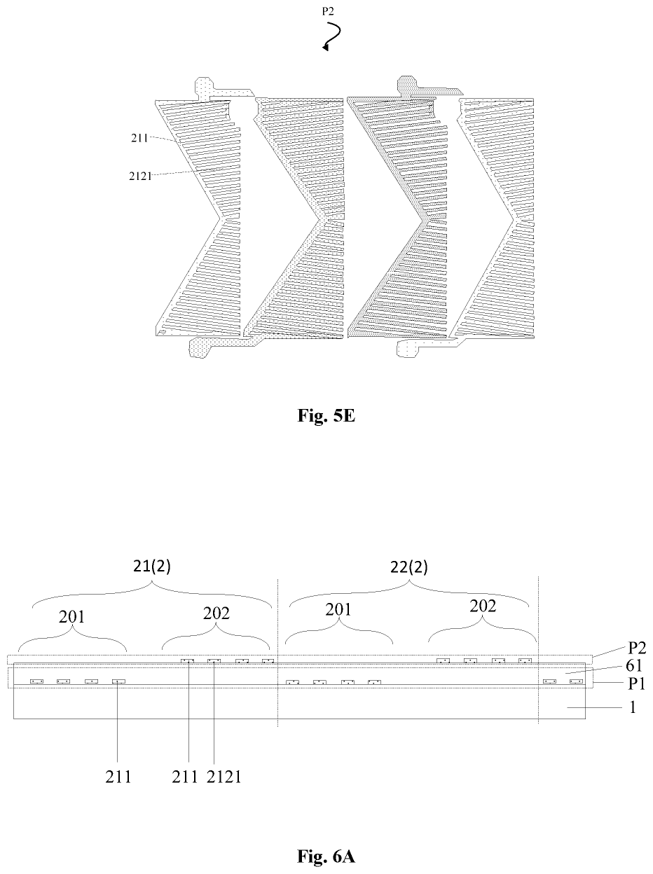

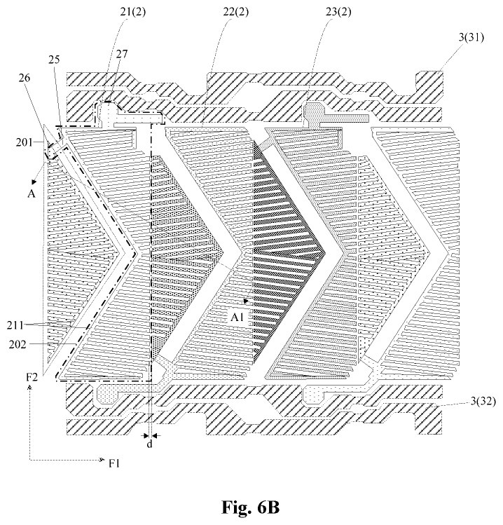

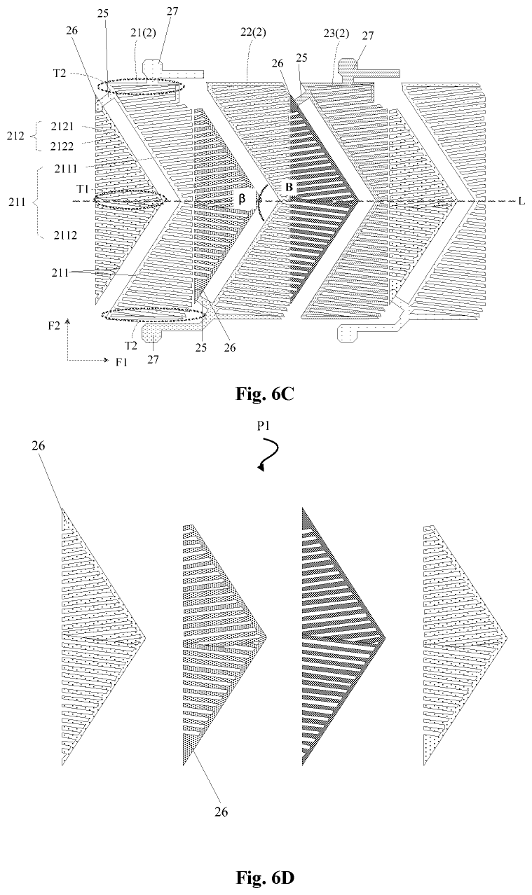

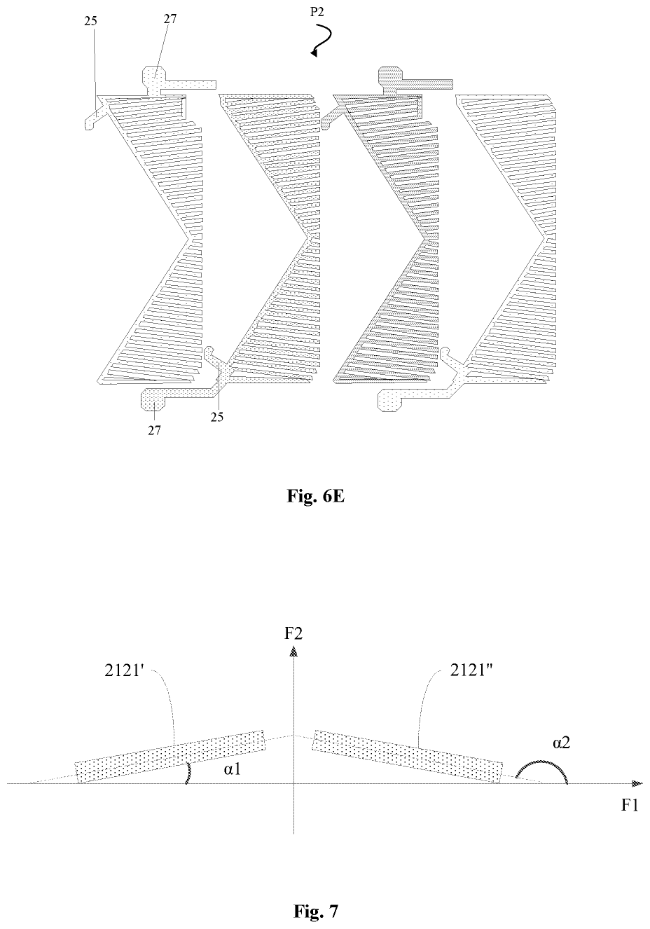

Embodiments of the present disclosure provide a display substrate, referring to FIG. 3A to FIG. 3E, FIG. 4A to FIG. 4E, FIG. 5A to FIG. 5E, and FIG. 6A to FIG. 6E. FIG. 3A is a schematic cross-sectional view along a dash line AA1 in FIG. 3B. FIG. 3B to FIG. 3D are schematic diagrams when the same pixel electrode is located in the same layer and includes one framework portion. FIG. 4A is a schematic cross-sectional view along a dash line AA1 in FIG. 4B. FIG. 4B to FIG. 4D are schematic diagrams when the same pixel electrode is located in the same layer and includes two framework portions. FIG. 5A is a schematic cross-sectional view along a dash line AA1 in FIG. 5B. FIG. 5B to FIG. 5D are schematic diagrams when the same pixel electrode is located in different layers and includes two framework portions with orthographic projections that are overlapped. FIG. 6A is a schematic cross-sectional view along a dash line AA1 in FIG. 6B. FIG. 6B to FIG. 6D are schematic diagrams when the same pixel electrode is located in different layers and includes two framework portions with orthographic projections that are not overlapped.

The display substrate includes: a base substrate 1: a plurality of gate lines 3, where the plurality of gate lines 3 are located on a side of the base substrate 1, and extend in a first direction F1; and a plurality of pixel electrodes 2, where the plurality of pixel electrodes 2 are distributed in arrays. Pixel electrodes 2 in the same row are electrically connected to at least one gate line 3. In the pixel electrodes 2 in the same row; at least adjacent parts of two adjacent pixel electrodes 2 are distributed in a split-level manner. Specifically, for example, as shown in FIG. 3A to FIG. 3E or FIG. 4A to FIG. 4E, the pixel electrodes 2 in the same row may include a first pixel electrode 21, a second pixel electrode 22, and a third pixel electrode 23. The entire first pixel electrode 21 and the entire second pixel electrode 22 that are adjacent are respectively located in different layers. Alternatively, in another example, as shown in FIG. 5A to FIG. 5E or FIG. 6A to FIG. 6E, the right part of the first pixel electrode 21 and the left part of the second pixel electrode 22 are respectively located in different layers.

In embodiments of the present disclosure, in the pixel electrodes 2 in the same row, at least adjacent parts of two adjacent pixel electrodes 2 are distributed in a split-level manner, so that a spacing d between the adjacent pixel electrodes 2 can be further reduced, a dark display area between the adjacent pixel electrodes 2 can be reduced, and when the display substrate provided in the embodiments of the present disclosure is applied to a 3D display device, moiré patterns can be mitigated, to thereby improve a display effect.

During specific implementation, the base substrate 1 may be selected according to an actual case. Specifically, the base substrate 1 may include film layers such as an insulating layer and a metal layer.

It needs to be noted that the pixel electrodes 2 in the same row are electrically connected to the at least one gate line 3. The pixel electrodes 2 in the same row may be not directly connected to the at least one gate line 3, for example, electrically connected by a thin-film transistor.

In a possible implementation, as shown in FIG. 3B, FIG. 4B, FIG. 5B, and FIG. 6B, in a direction parallel to the first direction F1 and in the pixel electrodes 2 in the same row; a minimum spacing d between two adjacent pixel electrodes 2 ranges from 0 μm to 2 μm. In embodiments of the present disclosure, the adjacent pixel electrodes 2 are disposed in a split-level manner, so that the minimum spacing d between two adjacent pixel electrodes 2 ranges from 0 μm to 2 μm. Within the range of the spacing, there can be basically no dark area between the adjacent pixel electrodes 2.

It needs to be noted that in the foregoing drawings, to illustrate the structure of the gate lines 3 and the pixel electrodes 2 more clearly, the structure of other film layers is not shown. However, the embodiments of the present disclosure are not limited thereto. Specifically. for example, a first insulating layer 61 may be further disposed between the pixel electrodes 2 located in different layers.

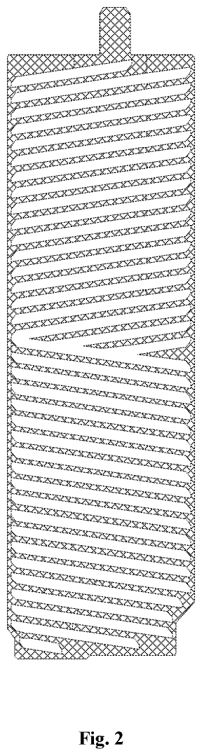

A liquid crystal display (LCD) panel has characteristics such as being light and thin. power saving, and free of radiation and is widely applied. The operating principle of the LCD panel is to change a voltage difference between two ends of a liquid crystal layer to change an arrangement status of liquid crystal molecules in the liquid crystal layer, thereby changing the light transmittance of the liquid crystal layer to display an image. During specific implementation, a display panel in the embodiments of the present disclosure may be a liquid crystal display panel. For the liquid crystal display panel, the structural design of a conventional pixel electrode is shown in FIG. 2. An electrode framework (used for transmitting a signal) is provided at a circumference of an edge of the pixel electrode. A plurality of transverse slits that are provided inside the pixel electrode. Liquid crystal is arranged along the slits. However, at the circumference of the edge of the pixel electrode, because the structure of the electrode framework causes an arrangement disorder of liquid crystal at the edge of the pixel electrode to form a dark display area. Therefore, there is a large dark display area between adjacent subpixels, which is not conducive to the elimination of moiré patterns. In the foregoing display substrate provided in the embodiments of the present disclosure, a dark display area between the adjacent pixel electrodes 2 can be reduced, thereby mitigating moiré patterns, and improving a display effect.

During specific implementation, the display substrate provided in the embodiments of the present disclosure may be applied to a liquid crystal display (LCD). LCD panel has been widely used due to its light and thin appearance, power saving and non-radiation characteristics. The operating principle of the LCD panel is to change a voltage difference between two ends of a liquid crystal layer to change an arrangement status of liquid crystal molecules in the liquid crystal layer, thereby changing the light transmittance of the liquid crystal layer to display an image.

In a possible implementation, with reference to FIG. 3A. FIG. 4A. FIG. 5A, and FIG. 6A, the display substrate includes two laminated electrode layers. The two electrode layers include a first electrode layer P1 and a second electrode layer P2 located on a side of the first electrode layer P1 away from the base substrate 1. The plurality of pixel electrodes 2 are distributed in the two electrode layers. Specifically, a first insulating layer 61 may be further disposed between the two electrode layers. In embodiments of the present disclosure, when the two adjacent pixel electrodes 2 are distributed in a split-level manner, the plurality of pixel electrodes are respectively distributed in the two electrode layers, so that a distribution layer quantity of electrode layers for distributing the pixel electrodes 2 can be reduced, thereby reducing the manufacturing complexity of the display substrate.

In a possible implementation, with reference to FIG. 3A or FIG. 4A, in the pixel electrodes 2 in the same row, the same pixel electrode 2 is located in the same electrode layer, and two adjacent pixel electrodes 2 are respectively located in different electrode layers. Specifically, for example, as shown in FIG. 3A or FIG. 4A, the pixel electrode 2 on the left side is located in the second electrode layer P2, and the pixel electrode 2 on the right side is located in the first electrode layer P1. Compared with that different parts of the same pixel electrode 2 are disposed in different layers, it is further necessary to consider connecting and communicating different parts of the same pixel electrode 2. In embodiments of the present disclosure, with each pixel electrode 2 as a whole, the same pixel electrode 2 is located in the same electrode layer, and the two adjacent pixel electrodes 2 are respectively located in different electrode layers, so that while moiré patterns of the display substrate can be mitigated, thereby simplifying a manufacturing process of the display substrate.

During specific implementation, the same pixel electrode 2 is located in the same electrode layer. When two adjacent pixel electrodes 2 are respectively located in different electrode layers, the pixel electrode 2 may include one framework portion 211, or may include two framework portions 211. Details are described below:

For example, as shown in FIG. 3A to FIG. 3E, each pixel electrode 2 includes a framework portion 211 with a body direction extending perpendicular to the first direction F1 and branch portions 2121 extending from two side edges of the framework portion 211. Specifically, each pixel electrode 2 includes one framework portion 211, and the branch portions 2121 extend from two sides of the framework portion 211.

For example, as shown in FIG. 4A to FIG. 4E, each pixel electrode 2 includes two framework portions 211 with a body direction extending perpendicular to the first direction F1 and having a gap, and branch portions 2121 extending from a side of each framework portion 211 away from the gap. The display substrate further includes: a connecting portion 24 extending in the first direction F1. An orthographic projection of the connecting portion 24 onto the base substrate 1 is at least located in the gap between the two framework portions 211. The two framework portions 211 of the same pixel electrode 2 are connected by the connecting portion 24. Specifically, the connecting portion 24 may be distributed in the same layer as the pixel electrode 2. Specifically, the connecting portion 24 may be located in a different layer from the pixel electrode 2. The two framework portions 211 of the same pixel electrode 2 are connected and in communication through perforation. In this case, the orthographic projection of the connecting portion 24 onto the base substrate 1 may further include a region (not shown in the figure) overlapped with the two framework portions 211.

Specifically, when the same pixel electrode 2 is located in the same layer and the adjacent pixel electrodes 2 are located in different layers, as shown in FIG. 3C to FIG. 3E and FIG. 4C to FIG. 4E, for example, the second pixel electrode 2 and the fourth pixel electrode 2 from the left in FIG. 3C or FIG. 4C may be located in the first electrode layer P1, and the first pixel electrode 2 and the third pixel electrode 2 from the left in FIG. 3C or FIG. 4C may be located in the second electrode layer P2. Certainly, during specific implementation, the first pixel electrode 2 and the third pixel electrode 2 from the left in FIG. 3C or FIG. 4C may be located in the first electrode layer P1, and the second pixel electrode 2 and the fourth pixel electrode 2 from the left in FIG. 3C or FIG. 4C may be located in the second electrode layer P2.

In a possible implementation, with reference to FIG. 5A to FIG. 5E and FIG. 6A to FIG. 6E, each pixel electrode 2 includes a first sub-electrode 201 and a second sub-electrode 202 sequentially arranged parallel to the first direction F1, the first sub-electrode 201 and the second sub-electrode 202 of the same pixel electrode 2 are respectively located in different electrode layers, and the first sub-electrode 201 and the second sub-electrode 202 of the same pixel electrode 2 are in communication through a via hole. Specifically, for example, as shown in FIG. 5A, the first sub-electrode 201 of the pixel electrode 2 is located in the first electrode layer P1, and the second sub-electrode 202 is located in the second electrode layer P2. Certainly, during specific implementation, the first sub-electrode 201 of the pixel electrode 2 may be located in the second electrode layer P2, and the second sub-electrode 202 may be located in the first electrode layer P1.

During specific implementation, when the first sub-electrode 201 and the second sub-electrode 202 of the same pixel electrode 2 are respectively located in different electrode layers, each of the first sub-electrode 201 and the second sub-electrode 202 may have a framework portion. Specifically, with reference to FIG. 5A to FIG. 5E and FIG. 6A to FIG. 6E, each of the first sub-electrode 201 and the second sub-electrode 202 includes: a framework portion 211 with a body direction extending perpendicular to the first direction F1 and branch portions 2121 extending from a side of each framework portion 211 away from the other framework portion 211.

In a possible implementation, with reference to FIG. 5A to FIG. 5E, an orthographic projection of the framework portion 211 of the first sub-electrode 201 onto the base substrate 1 is approximately overlapped with an orthographic projection of the framework portion 211 of the second sub-electrode 202 onto the base substrate 1. In this case, the first sub-electrode 201 and the second sub-electrode 202 of the same pixel electrode 2 may be in communication through perforation in an overlap region of the two framework portions 211. Specifically, communication is performed through perforation at a midpoint (a point B shown in FIG. 5C) of the framework portion 211. Alternatively, communication may be through perforation at a start end or tail end of the framework portion 211. It may be understood that due to a process error in an actual manufacturing process, it is required that the orthographic projection of the framework portion 211 of the first sub-electrode 201 onto the base substrate 1 be completely overlapped with the orthographic projection of the framework portion 211 of the second sub-electrode 202 onto the base substrate 1, and the difficulty is high. Therefore, in embodiments of the present disclosure, the orthographic projection of the framework portion 211 of the first sub-electrode 201 onto the base substrate 1 is approximately overlapped with the orthographic projection of the framework portion 211 of the second sub-electrode 202 onto the base substrate 1, and it may be understood that an overlap area of the two is 70% to 100%.

In a possible implementation, with reference to FIG. 6A to FIG. 6E, an orthographic projection of the framework portion 211 of the first sub-electrode 201 onto the base substrate 1 and an orthographic projection of the framework portion 211 of the second sub-electrode 202 onto the base substrate 1 are parallel to each other, and have a gap therebetween. Specifically, the first sub-electrode 201 further includes: a first portion 26 connected to the framework portion 211 and extending away from a side of the second sub-electrode 202: the second sub-electrode 202 further includes: an extending portion 25 connected to the framework portion 211 and extending toward a side of the first sub-electrode 201; and an orthographic projection of the first portion 26 onto the base substrate 1 and an orthographic projection of the extending portion 25 onto the base substrate 1 have an overlap region, and the first portion 26 and the extending portion 25 are connected by a perforation at the overlap region.

In a possible implementation, with reference to FIG. 6B to FIG. 6E, the second sub-electrode 202 further includes a protruding portion 27. The protruding portion 27 is configured to be electrically connected a source or a drain. The extending portion 25 and the protruding portion 27 are located at the same end of the pixel electrode 2 to which the extending portion and the protruding portion belong. Specifically, as shown in FIG. 6C, in the second pixel electrode 2 from the left, the extending portion 25 and the protruding portion 27 are located at the lower end of the pixel electrode 2 to which the extending portion and the protruding portion belong.

During specific implementation, with reference to FIG. 3A to FIG. 3E. FIG. 4A to FIG. 4E. FIG. 5A to FIG. 6E, and FIG. 6A to FIG. 6E, the adjacent branch portions 2121 have a slit 2122, and the plurality of branch portions 2121 and the plurality of slits 2122 form a comb structure 212. Specifically, the shape of the framework portion 211 may have a broken line form. The framework portion 211 in the broken line form can prevent moiré patterns caused by interference between gratings of a 3D display device, so that moiré patterns in a display screen can be further eliminated, thereby improving a display effect.

During specific implementation, with reference to FIG. 3A to FIG. 3E. FIG. 4A to FIG. 4E. FIG. 5A to FIG. 6E, and FIG. 6A to FIG. 6E, the framework portion 211 is divided into a first sub-framework portion 2111 and a second sub-framework portion 2112 along a bending point B. The branch portions 2121 on two sides of the first sub-framework portion 2111 are in one-to-one correspondence and are located in the same straight line, and the branch portions 2121 on two sides of the second sub-framework portion 2112 are in one-to-one correspondence and are located in the same straight line. This is conducive to regular arrangement of liquid crystal molecules, thereby improving a display effect.

During specific implementation, with reference to FIG. 3A to FIG. 3E. FIG. 4A to FIG. 4E. FIG. 5A to FIG. 6E, and FIG. 6A to FIG. 6E, the branch portions 2121 connected to the first sub-framework portion 2111 are approximately parallel, and the branch portions 2121 connected to the second sub-framework portion 2112 are approximately parallel. In this case, when the liquid crystal display panel performs display, all liquid crystal molecules may be regularly arranged, thereby improving a display effect.

During specific implementation, in the foregoing display panel provided in the embodiments of the present disclosure, as shown in FIG. 7, the branch portions 2121 (represented by 2121′ in FIG. 7) connected to the first sub-framework portion 2111 and the row direction F1 have a first tilt angle α1, and the branch portions 2121 (represented by 2121″ in FIG. 7) connected to the second sub-framework portion 2112 and the row direction F1 have a second tilt angle α2. The first tilt angle α1 and the second tilt angle α2 are complementary to each other. The same pixel electrode has branch portions 2121 with tilt angles complementary to each other. In this arrangement manner, the same pixel electrode may have complementary brightness, so that transverse patterns can be prevented.

During specific implementation, in the foregoing display panel provided in the embodiments of the present disclosure, as shown in FIG. 3A to FIG. 3E. FIG. 4A to FIG. 4E. FIG. 5A to FIG. 6E, and FIG. 6A to FIG. 6E, the pixel electrodes 21 have a central line L extending in the row direction F1. The bending point B is approximately located on the central line L. Because a manufacturing process affected, the position of the bending point B and the central line L may have a certain error. This structure may mitigate moiré patterns to the largest extent.

During specific implementation, in the foregoing display panel provided in the embodiments of the present disclosure, as shown in FIG. 3C. FIG. 4C. FIG. 5C, and FIG. 6C, the framework portion 211 has a bending angle ß at the position of a corresponding bending point B. At a position (at an elliptical dash line box T1) on a side of the bending angle ß and close to the bending point B, a plurality of branch portions 2121 correspondingly connected to the first sub-framework portion 2111 and the second sub-framework portion 2112 are electrically connected. On opposite sides of the bending angle ß and at edges (at an elliptical dash line box T2) away from two sides of the bending point B, a plurality of branch portions 2121 correspondingly connected to the first sub-framework portion 2111 are electrically connected, and a plurality of branch portions 2121 correspondingly connected to the second sub-framework portion 2112 are electrically connected. Ends of the branch portions 2121 at the remaining positions away from the framework portion 211 are independent of each other. That is, an open comb structure is disposed at an edge of the structure of the pixel electrode, so that orderly arrangement of liquid crystal at an edge of the pixel electrode can be implemented, a dark display area between subpixels can be reduced, and moiré patterns can be mitigated, thereby improving a display effect.

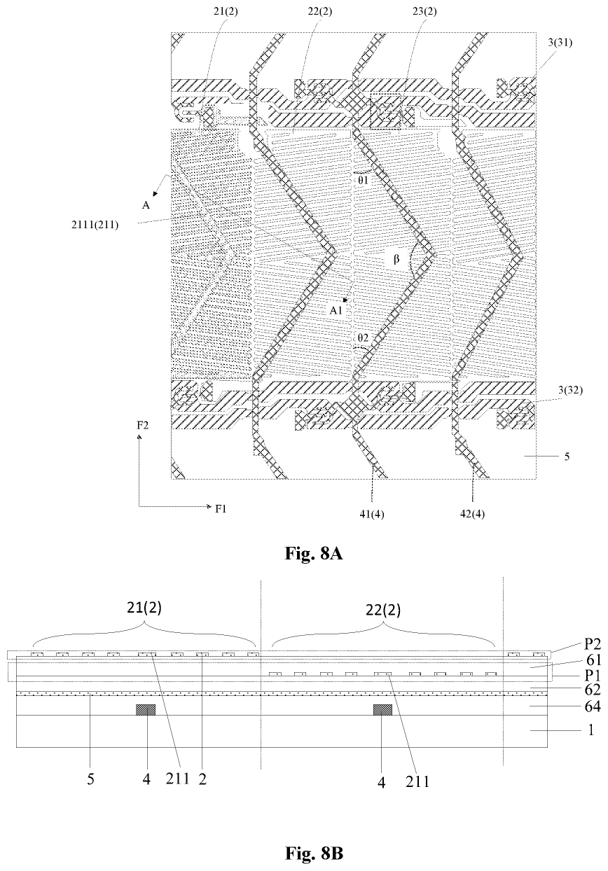

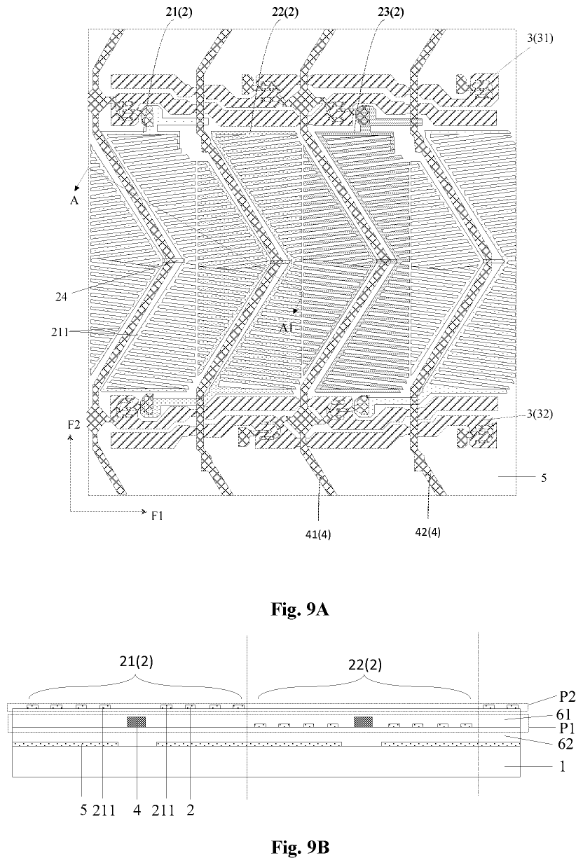

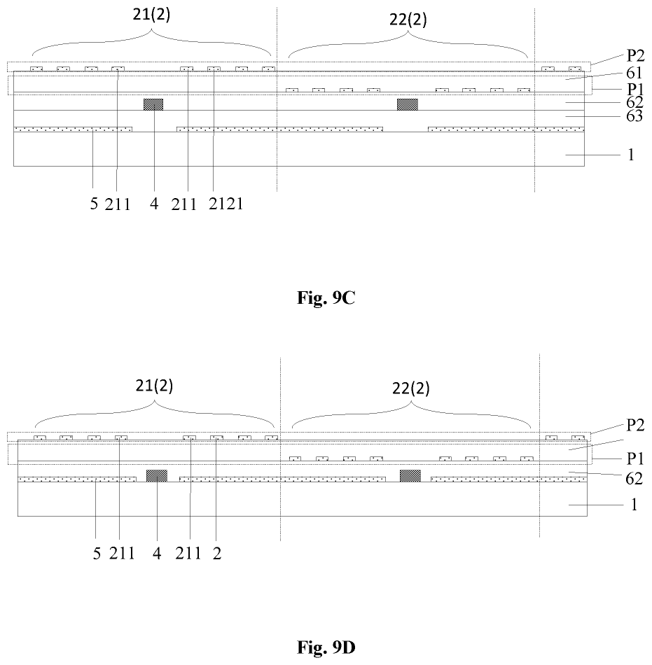

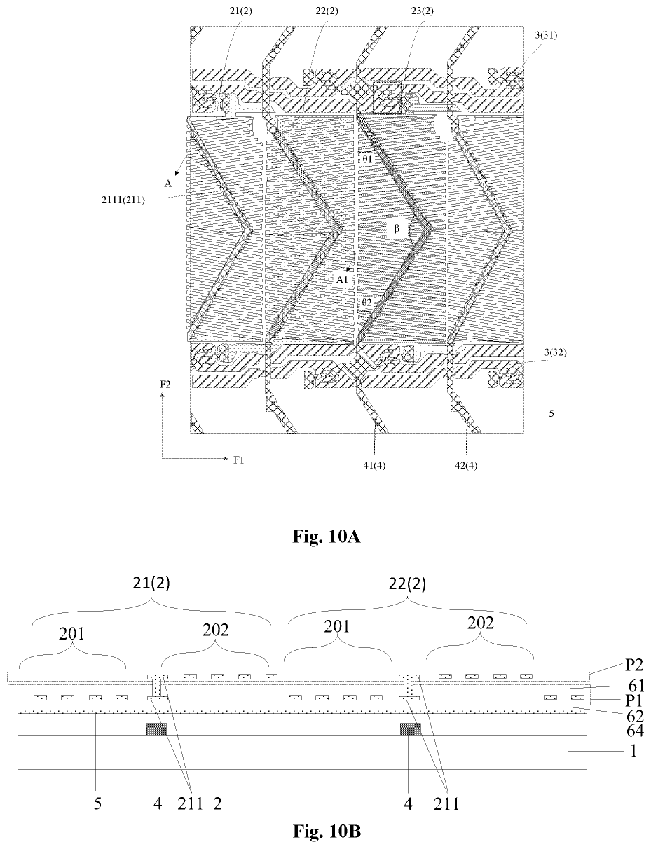

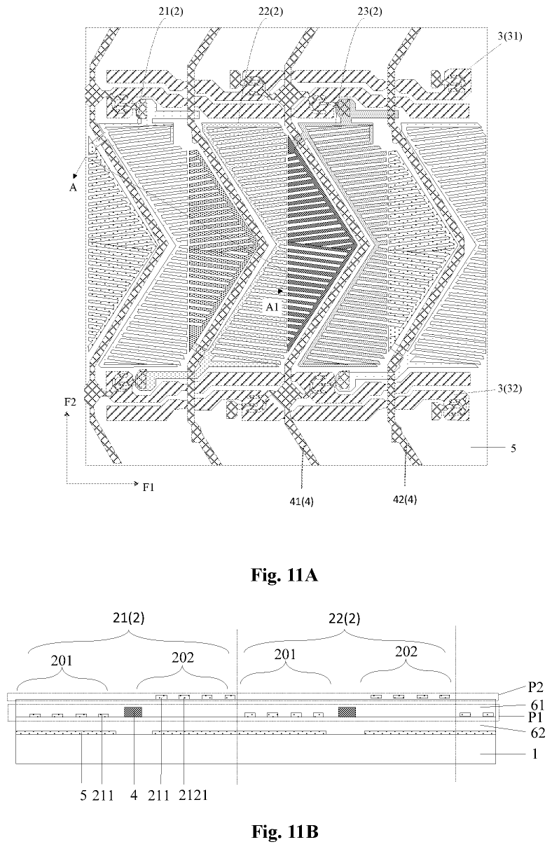

In a possible implementation, as shown in FIG. 8A. FIG. 8B. FIG. 9A to FIG. 9D. FIG. 10A. FIG. 10B. FIG. 11A, and FIG. 11B. FIG. 8A is a schematic diagram of a display substrate after a data line and a common electrode layer are laminated in FIG. 3B. FIG. 8B is a schematic cross-sectional view along a dash line AA1 in FIG. 8A. FIG. 9A is a schematic diagram of a display substrate after a data line and a common electrode layer are laminated in FIG. 4B. FIG. 9B is a schematic cross-sectional view along a dash line AA1 in FIG. 9A. FIG. 10A is a schematic diagram of a display substrate after a data line and a common electrode layer are laminated in FIG. 5B. FIG. 10B is a schematic cross-sectional view along a dash line AA1 in FIG. 10A. FIG. 11A is a schematic diagram of a display substrate after a data line and a common electrode layer are laminated in FIG. 6B. FIG. 11B is a schematic cross-sectional view along a dash line AA1 in FIG. 11A. The display substrate further includes a data line 4 with a body direction extending perpendicular to the first direction F1, and further includes a common electrode layer 5; and a partial orthographic projection of the data line 4 onto the base substrate 1 is located in a region in which the orthographic projection of the pixel electrode 2 onto the base substrate 1 is located.

In a possible implementation, with reference to FIG. 8A and FIG. 8B, when the same pixel electrode 2 is located in the same electrode layer, two adjacent pixel electrodes 2 are respectively located in different electrode layers, and the pixel electrode 2 includes one framework portion 211, an orthographic projection of the data line 4 onto the base substrate 1 is approximately overlapped with an orthographic projection of the framework portion 211 onto the base substrate 1. It may be understood that due to a process error in an actual manufacturing process, it is required that the orthographic projection of the data line 4 onto the base substrate 1 be completely overlapped with the orthographic projection of the framework portion 211 onto the base substrate 1, and the difficulty is high. Therefore, in embodiments of the present disclosure, the orthographic projection of the data line 4 onto the base substrate 1 is approximately overlapped with the orthographic projection of the framework portion 211 onto the base substrate 1, and it may be understood that is an overlap area of the two is 70% to 100%.

In a possible implementation, with reference to FIG. 10A and FIG. 10B, when the pixel electrode 2 includes two framework portions 211 and orthographic projections of the two framework portions 211 onto the base substrate 1 are approximately overlapped, an orthographic projection of the data line 4 onto the base substrate 1 is approximately overlapped with the orthographic projections of the framework portions 211 onto the base substrate 1.

Specifically, as shown in FIG. 8B and FIG. 10B, the data line 4 may be located between the first electrode layer P1 and the base substrate 1. The display substrate may further include an organic film layer 64 located between the first electrode layer P1 and the data line 4. Specifically, the common electrode layer 5 may be further disposed between the data line 4 and the first electrode layer P1, a second insulating layer 62 may further be provided between the common electrode layer 5 and the first electrode layer P1, and the organic film layer 64 may be located between the common electrode layer 5 and the data line 4. In embodiments of the present disclosure, as shown in FIG. 8B and FIG. 10B, the display substrate may be an organic film layer product. That is, because the data line 4 is overlapped with the pixel electrodes 21 and the common electrode layer 5, the organic film layer 64 is disposed between the first electrode layer P1 and the data line 4, so that coupling capacitance can be reduced by using an organic film process, thereby ensuring a pixel charging rate and screen quality.

In a possible implementation, as shown in FIG. 9A to FIG. 9D. FIG. 11A, and FIG. 11B, the display substrate in the embodiments of the present disclosure may be a non-organic film layer product. That is, the orthographic projection of the data line 4 onto the base substrate 1 is not overlapped with the orthographic projection of the framework portion 211 onto the base substrate 1, and an organic film may be not disposed between the data line 4 and the first electrode layer P1. The pixel electrode 2 includes two framework portions 211 and the two framework portions 211 have a gap, the orthographic projection of the data line 4 onto the base substrate 1 is located in the gap between the two framework portions 211 at the base substrate.

Specifically, in a possible implementation, with reference to FIG. 9A to FIG. 9D, when the same pixel electrode 2 is located in the same electrode layer, two adjacent pixel electrodes 2 are respectively located in different electrode layers, and the pixel electrode 2 includes the two framework portions 211, the data line 4 may be disposed in the same layer as the first electrode layer P1, or may be not disposed in the same layer as the first electrode layer P1. Details are described below:

For example, as shown in FIG. 9B, the data line 4 may be disposed in the same layer as the first electrode layer P1. The common electrode layer 5 may be located between the first electrode layer P1 and the base substrate 1. The second insulating layer 62 may be further disposed between the common electrode layer 5 and the first electrode layer P1. When the data line 4 and the first electrode layer P1 are disposed in the same layer, the connecting portion 24 in the pixel electrode 2 that is in the same layer as the data line 4 in FIG. 9A may be not disposed in the same layer as the pixel electrode 2, to avoid affecting the normal display of the display substrate when the connecting portion 24 and the data line 4 are cross-connected. Specifically, in a possible implementation, for the connecting portion 24 located in the pixel electrode 2 in the first electrode layer P1, the connecting portion 24 may be disposed in the second electrode layer P2, to make two parts of the same pixel electrode 2 in the first electrode layer P1 connected and in communication through perforation.

For example, as shown in FIG. 9C, the data line 4 is located between the first electrode layer P1 and the base substrate 1. Specifically, the common electrode layer 5 is located between the data line 4 and the base substrate 1. Specifically, the second insulating layer 62 may be disposed between the data line 4 and the first electrode layer P1. A third insulating layer 63 may be disposed between the data line 4 and the common electrode layer 5.

In another example, as shown in FIG. 9D, the data line 4 is located between the first electrode layer P1 and the base substrate 1. Specifically, the data line 4 and the common electrode layer 5 are disposed in the same layer. Specifically, the second insulating layer 62 may be disposed between the data line 4 and the first electrode layer P1.

Specifically, in a possible implementation, with reference to FIG. 11A or FIG. 11B, when the same pixel electrode 2 is located in the same electrode layer, two adjacent pixel electrodes 2 are respectively located in different electrode layers, the pixel electrode 2 includes the two framework portions 211, and the orthographic projections of the two framework portions 211 onto the base substrate 1 have a gap, with reference to FIG. 11B, the data line 4 may be disposed in the same layer as the first electrode layer P1. Specifically, the data line 4 may be disposed in the same layer as the first sub-electrode 201 in the pixel electrode 2. The common electrode layer 5 may be located between the data line 4 and the base substrate 1. The second insulating layer 62 may be further disposed between the common electrode layer 5 and the data line 4.

In a possible implementation, with reference to FIG. 8A to FIG. 11B and FIG. 12, the shape of the orthographic projection of the data line 4 onto the base substrate 1 may have a broken line form. The data line 4 in a broken line form can prevent moiré patterns caused by interference between gratings of a 3D display device, so that moiré patterns in a display screen can be further eliminated, thereby improving a display effect.

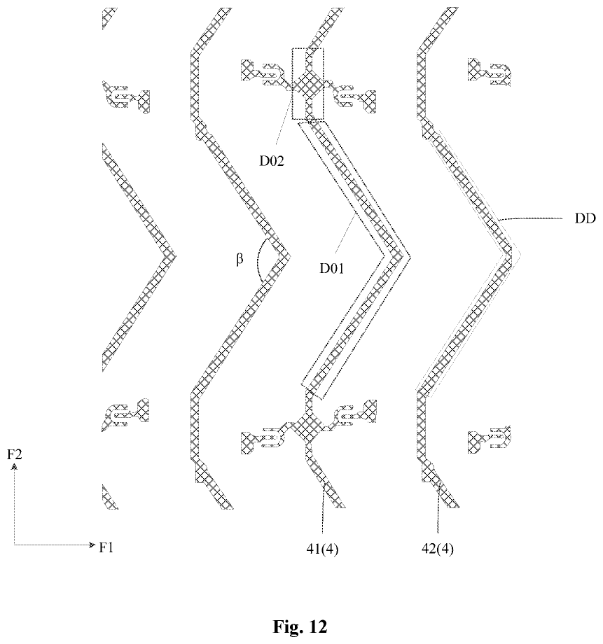

Specifically, when the orthographic projection of the data line 4 onto the base substrate 1 is overlapped with the orthographic projection of the framework portion 211 onto the base substrate 1, with reference to FIG. 8A. FIG. 10A, and FIG. 12, the orthographic projection of the data line 4 onto the base substrate 1 and the orthographic projection of the pixel electrode 2 onto the base substrate 1 have an overlap region DD, and the shape of the overlap region DD is in a broken line form.

Specifically, with reference to FIG. 8A. FIG. 10A, and FIG. 12, when the orthographic projection of the framework portion 211 of the pixel electrode 2 onto the base substrate 1 is approximately overlapped with an orthographic projection of the overlap region DD onto the base substrate 1, the framework portion 211 of the pixel electrode 2 is arranged along the data line 4, so that a liquid crystal disorder region is overlapped with a metal shading region (the overlap region DD), the remaining part of the pixel electrode 2 uses a transverse open comb structure, thereby eventually implementing minimization of a dark area between subpixels.

Specifically, with reference to FIG. 8A. FIG. 10A, and FIG. 12, the overlap region DD and a column direction F2 form an isosceles triangle, and a bending angle ß of the overlap region DD is greater than 90° and less than 180º. In this way, a moiré patterns defect can be further mitigated. Specifically, the bending angle ß of the overlap region DD may be set to 114º. In addition, an included angle θ1 between the overlap region DD in a broken line form and the column direction F2 of a subpixel P may be set to 32°, and another included angle θ2 between the overlap region DD in a broken line form and a column direction F1 of the subpixel P may be set to 32°. A long side of the bending angle ß is arranged along a long side (the column direction F2) of the pixel electrode 2, and a width of the shading region (the long side of B) is reduced to 2 μm as much as possible to eliminate moiré patterns, and widths of the remaining two sides are not limited. Certainly, in actual application. ß may be designed according to requirements in the actual application. Specific values of 01 and 02 are not limited.

Specifically, one data line 4 (41 or 42) may be correspondingly set for one column of pixel electrodes 2. With reference to FIG. 12, each data line 4 includes a first sub-data line D01 and a second sub-data line D02 that are electrically connected to each other. An orthographic projection of the first sub-data line D01 onto the base substrate 1 and an orthographic projection of a region in which a corresponding pixel electrode 2 is located onto the base substrate 1 form the overlap region DD. An orthographic projection of the second sub-data line D02 onto the base substrate 1 and an orthographic projection of the region in which the pixel electrode 2 is located onto the base substrate 1 are not overlapped. For example, the orthographic projection of the second sub-data line D02 onto the base substrate 1 is located between orthographic projections of regions in which adjacent pixel electrodes 2 are located onto the base substrate 1. In this way, the data line 4 can be reused as a shading pattern to prevent interference with a grating, so that process manufacturing difficulty can be reduced, thereby reducing the thickness of the display panel.

It needs to be noted that FIG. 3A to FIG. 11B are only illustratively described by using the display substrate as a double-gate structure. That is, one row of pixel electrodes 2 corresponds two gate lines (G1, G2), and orthographic projections of the gate lines (G1, G2) onto the base substrate 1 are located between orthographic projections of regions in which two adjacent rows of pixel electrodes 2 are located onto the base substrate 1. In addition, two gate lines (31, 32) corresponding to the pixel electrodes 2 in the same row are respectively located on two sides of the corresponding row of pixel electrodes 2. For example, one gate line (for example, 31) in the two gate lines (31, 32) corresponding to the pixel electrodes 2 in the same row is electrically connected to thin-film transistors corresponding to odd-numbered columns of pixel electrodes 2 in the row; and the other gate line (for example, 32) is electrically connected to thin-film transistors corresponding to even-numbered columns of pixel electrodes 2 in the row: The gate line (for example, 31) electrically connected to the thin-film transistors in the odd-numbered columns of pixel electrodes 2 in the row may be disposed above the row; and the gate line (for example, 32) electrically connected to the thin-film transistors in the even-numbered columns of pixel electrodes 2 in the row may be disposed below the row. During specific implementation, the display substrate may be a single-gate structure. That is, the gate line 3 extends in the row direction F1 of the pixel electrode 2. One row of pixel electrodes 2 corresponds to one gate line 3. This is not limited in the embodiments of the present disclosure.

Based on the same inventive concept, an embodiment of the present disclosure further provides a display panel, including the display substrate provided in the foregoing embodiment of the present disclosure.

Based on the same inventive concept, an embodiment of the present disclosure further provides a display device, including the display panel provided in the foregoing embodiment of the present disclosure.

In embodiments of the present disclosure, in the pixel electrodes 2 in the same row; at least adjacent parts of two adjacent pixel electrodes 2 are distributed in a split-level manner, so that a spacing d between the adjacent pixel electrodes 2 can be further reduced, a dark display area between the adjacent pixel electrodes 2 can be reduced, and when the display substrate provided in the embodiments of the present disclosure is applied to a 3D display device, moiré patterns can be mitigated, thereby improving a display effect.

Although preferred embodiments of the present invention are described, once acquiring basic innovative concepts, a person skilled in the art may make other changes and modifications to these embodiments. Therefore, the appended claims intend to be explained to include preferred embodiments and all changes and modifications that fall within the scope of the present invention.

Obviously, persons skilled in the art can make various modifications and variations to the embodiments of the present invention without departing from the spirit and scope of the embodiments of the present invention. In this way, if these modifications and variations to the embodiments of the present invention fall within the scope of claims of the present invention and equivalent technologies thereof, the present invention also intends to cover these modifications and variations.

1. A display substrate, comprising:
a base substrate;
a plurality of gate lines, located on a side of the base substrate, and extending in a first direction; and
a plurality of pixel electrodes, distributed in arrays, wherein pixel electrodes in a same row are electrically connected to at least one gate line, and in the pixel electrodes in the same row, at least adjacent parts of two adjacent pixel electrodes are distributed in a split-level manner.

2. The display substrate according to claim 1, wherein the display substrate comprises two laminated electrode layers, and the two electrode layers comprise a first electrode layer and a second electrode layer located on a side of the first electrode layer away from the base substrate; and
the plurality of pixel electrodes are distributed in the two electrode layers.

3. The display substrate according to claim 2, wherein in the pixel electrodes in the same row, a same pixel electrode is located in a same electrode layer, and two adjacent pixel electrodes are respectively located in different electrode layers.

4. The display substrate according to claim 3, wherein each pixel electrode comprises a framework portion with a body direction extending perpendicular to the first direction and branch portions extending from two side edges of the framework portion.

5. The display substrate according to claim 3, wherein each pixel electrode comprises two framework portions with a body direction extending perpendicular to the first direction and having a gap, and branch portions extending from a side of each framework portion away from the gap; and
the display substrate further comprises: a connecting portion extending in the first direction,
wherein an orthographic projection of the connecting portion onto the base substrate is at least located in the gap between the two framework portions, and the two framework portions of the same pixel electrode are connected by the connecting portion.

6. The display substrate according to claim 2, wherein each pixel electrode comprises a first sub-electrode and a second sub-electrode sequentially arranged parallel to the first direction, the first sub-electrode and the second sub-electrode of the same pixel electrode are respectively located in different electrode layers, and the first sub-electrode and the second sub-electrode of the same pixel electrode are in communication through a via hole.

7. The display substrate according to claim 6, wherein each of the first sub-electrode and the second sub-electrode comprises: a framework portion with a body direction extending perpendicular to the first direction and branch portions extending from a side of each framework portion away from the other framework portion.

8. The display substrate according to claim 7, wherein an orthographic projection of the framework portion of the first sub-electrode onto the base substrate is approximately overlapped with an orthographic projection of the framework portion of the second sub-electrode onto the base substrate.

9. The display substrate according to claim 7, wherein an orthographic projection of the framework portion of the first sub-electrode onto the base substrate and an orthographic projection of the framework portion of the second sub-electrode onto the base substrate are parallel to each other, and have a gap therebetween.

10. The display substrate according to claim 9, wherein the first sub-electrode further comprises: a first portion connected to the framework portion and extending away from a side of the second sub-electrode;
the second sub-electrode further comprises: an extending portion connected to the framework portion and extending toward a side of the first sub-electrode; and
an orthographic projection of the first portion onto the base substrate and an orthographic projection of the extending portion onto the base substrate have an overlap region, and the first portion and the extending portion are connected by a perforation at the overlap region.

11. The display substrate according to claim 7, wherein the second sub-electrode further comprises a protruding portion, and the protruding portion is configured to be electrically connected a source or a drain; and
the extending portion and the protruding portion are located at the same end of the pixel electrode to which the extending portion and the protruding portion belong.

12. The display substrate according to claim 2, wherein the display substrate further comprises a data line with a body direction extending perpendicular to the first direction, and further comprises a common electrode layer; and a partial orthographic projection of the data line onto the base substrate is located in a region in which the orthographic projection of the pixel electrode onto the base substrate is located.

13. The display substrate according to claim 12, wherein when the pixel electrode comprises one framework portion, an orthographic projection of the data line onto the base substrate is approximately overlapped with an orthographic projection of the framework portion onto the base substrate.

14. The display substrate according to claim 12, wherein when the pixel electrode comprises two framework portions and orthographic projections of the two framework portions onto the base substrate are approximately overlapped, an orthographic projection of the data line onto the base substrate is approximately overlapped with the orthographic projections of the two framework portions onto the base substrate.

15. The display substrate according to claim 13, wherein the data line is located between the first electrode layer and the base substrate; and
the display substrate further comprises an organic film layer located between the first electrode layer and the data line.

16. The display substrate according to claim 12, wherein when the pixel electrode comprises two framework portions and the two framework portions have a gap, an orthographic projection of the data line onto the base substrate is located in the gap between the two framework portions at the base substrate.

17. The display substrate according to claim 16, wherein the data line is located in the first electrode layer; or the data line is located between the first electrode layer and the base substrate.

18. The display substrate according to claim 1, wherein in a direction parallel to the first direction and in the pixel electrodes in the same row, a minimum spacing between two adjacent pixel electrodes ranges from 0 μm to 2 μm.

19. A display panel, comprising a display substrate, wherein the display substrate comprises:
a base substrate;
a plurality of gate lines, located on a side of the base substrate, and extending in a first direction; and
a plurality of pixel electrodes, distributed in arrays, wherein pixel electrodes in a same row are electrically connected to at least one gate line, and in the pixel electrodes in the same row, at least adjacent parts of two adjacent pixel electrodes are distributed in a split-level manner.

20. A display device, comprising a display panel, wherein the display panel comprises a display substrate comprising:
a base substrate;
a plurality of gate lines, located on a side of the base substrate, and extending in a first direction; and
a plurality of pixel electrodes, distributed in arrays, wherein pixel electrodes in a same row are electrically connected to at least one gate line, and in the pixel electrodes in the same row, at least adjacent parts of two adjacent pixel electrodes are distributed in a split-level manner.
